(19) United States
(12) Patent Application Publication
(10) Pub. No.: US 2011/0211139 A1
(43) Pub. Date: Sep. 1, 2011

(54) DISPLAY DEVICE

(75) Inventor: Motomitsu Itoh, Osaka (JP)

(73) Assignee: SHARP KABUSHIKI KAISHA, Osaka (JP)

(21) Appl. No.: 13/126,996

(22) PCT Filed: Aug. 3, 2009
(86) PCT No.: PCT/JP2009/063748

§ 371 Date: Apr. 29, 2011

(30) Foreign Application Priority Data
Nov. 10, 2008 (JP) 2008-288158

(51) Int. Cl. G02F 1/1333; H05K 1/14

(52) U.S. Cl. 349/60; 361/749

(57) ABSTRACT

A liquid crystal display device 1 includes a liquid crystal panel (display unit) 2 having a plurality of pixels P to display information on the liquid crystal panel 2. The liquid crystal display device 1 is provided with printed circuit boards 10, and flexible printed circuit boards 9 connected electrically with the printed circuit boards 10. The printed circuit boards 10 are mounted on a frame (mounting member) 13 at the substantially central portion on a longer side (one side) to which the flexible printed circuit boards 9 are connected in the vicinity of the flexible printed circuit boards 9.

### TECHNICAL FIELD

The present invention relates to a display device which has a display unit having a plurality of pixels and displays information such as characters and images on the display unit.

### BACKGROUND ART

Recently, for example, liquid crystal display devices are being widely used in liquid crystal television screens, monitors, and cellular phones as flat panel displays which are thinner and lighter than conventional cathode-ray tubes. In such a liquid crystal display device, a liquid crystal panel having a plurality of pixels is used in a display unit for displaying information such as characters and images. The liquid crystal display device supplies a voltage signal according to a gradation value of information to be displayed for each of the plurality of pixels, so that a display operation is executed, and the information is displayed on the display surface.

In a conventional liquid crystal display device, as described in Patent Document 1 below, for example, flexible printed circuit boards and bus substrates (printed circuit boards) are connected sequentially to a liquid crystal panel to drive a plurality of source wires (data wires) and a plurality of gate wires (scan wires) provided on the liquid crystal panel. Also in the conventional liquid crystal display device, a board supporting means is disposed for supporting the bus substrates against the liquid crystal panel in such a way that both sides of the rectangular bus substrates hold the flexible printed-circuit boards in between. The conventional liquid crystal display device has been considered to be able to prevent separation of the flexible printed circuit boards and disconnection of inner wiring caused by thermal deformation in a heat shock test, by fixing the substrate supporting means and the bus substrates with a prescribed fixing means and by coupling the liquid crystal panel and the substrate supporting means with a fixing resin.

### RELATED ART DOCUMENT

### Patent Document

Patent Document 1: Japanese Patent Application Laid-Open Publication No. 2003-322870

### SUMMARY OF THE INVENTION

### Problem to be Solved by the Invention

In the conventional liquid crystal display device, however, the bus substrates are attached to the liquid crystal panel by using the substrate supporting means disposed on both sides of the bus substrates (printed circuit boards) in the longitudinal direction; therefore, when deformation such as elongation occurs in one or both of shorter sides because of a change in a surrounding environment such as temperature and humidity in the conventional liquid crystal display, the flexible printed circuit boards which are connected to the liquid crystal panel may suffer deformation such as elongation as the bus substrates deform. As a result, the conventional liquid crystal display device has a problem that the device cannot prevent damages such as cuts on the flexible printed circuits boards.

The present invention seeks to address the problem described above, and aims to provide a display device that prevents damages to the flexible printed circuit boards even if the printed circuit boards suffer deformation such as elongation.

### Means for Solving the Problem

To solve the above problem, a display device of the present invention, which has a display unit having a plurality of pixels and displays information in the display unit, includes a printed circuit board, and flexible printed circuit boards electrically connected to the printed circuit board. The printed circuit board are attached to a mounting member at a substantially central portion on one side thereof to which the flexible printed circuit boards are connected and in the vicinity of the flexible printed circuit boards.

In the display device configured as above, the printed circuit board is mounted on the mounting member at the substantially central portion on one side thereof to which the flexible printed circuit boards are connected and in the vicinity of the flexible printed circuit boards. In this configuration, unlike the above conventional art, even if the printed circuit board suffers deformation such as elongation, it is possible to suppress occurrence of deformation such as elongation therein on the flexible printed circuit board as the printed circuit board deforms. As a result, unlike the above conventional art, even if the printed circuit board suffers deformation such as elongation, it is possible to prevent damages on the flexible printed circuit boards.

In the above display device, a plurality of the flexible printed circuit boards are preferably connected electrically to, and are arranged in a line on one side of, the printed circuit board, and the printed circuit board is preferably attached to the mounting member in the vicinity of the substantially central ones of the plurality of the flexible printed circuit boards on the one side.

In this case, even if the printed circuit board suffers deformation such as elongation, each of the plurality of the flexible printed circuit boards are saved from being damaged.

The display device may have a bezel for housing the display unit and a frame attached to the bezel. The frame may have a pin member projecting into the printed circuit board. The printed circuit board may have an insertion hole in which the pin member is inserted, and may be attached to the frame as mounting member when the pin member is inserted in the insertion hole.

In this case, the printed circuit board is attached to the frame via the pin member.

The display device may have a bezel for housing the display unit, a frame attached to the bezel, and a chassis provided in and attached to the frame. The printed circuit board may be attached at least to the chassis as a mounting member with a screw member when the frame and the chassis are provided.

In this case, the printed circuit board is attached at least to the chassis with the screw member. Therefore, they are attached more stably.

In the display device, the screw member is preferably provided on the one side of the printed circuit board rather than the end side of the flexible printed circuit boards.

In this case, even if the printed circuit board suffers deformation such as elongation, the flexible printed circuit boards surely do not suffer deformation such as elongation. Thus it is possible to surely prevent damages to the flexible printed circuit boards.

In the display device, the chassis and the screw member are preferably made of metal, and the printed circuit board preferably is grounded via the screw member and the chassis.

In this case, the printed circuit board is grounded easily.

In the display device, the display unit preferably includes a liquid crystal panel, and the chassis preferably is a case for housing a light source for emitting illumination light in an illumination device which irradiates the liquid crystal panel with illumination light.

In this case, the liquid crystal display device can be made compact and can prevents damages to the flexible printed circuit boards.

In the display device, the flexible printed circuit boards may have drivers mounted thereon for driving the plurality of pixels.

In this case, it is possible to make the display device of simple structure.

### EFFECTS OF THE INVENTION

The present invention provides a display device capable of preventing damages to flexible printed circuit boards even if the printed circuit board suffers deformation such as elongation.

### BRIEF DESCRIPTION OF THE DRAWINGS

FIG. 1 is a schematic cross sectional view of a liquid crystal display device of Embodiment 1 of the present invention.

FIG. 2 is a diagram showing the configuration of main components of the liquid crystal panel shown in FIG. 1.

FIG. 3 is a plan view of the printed circuit boards and the flexible printed circuit boards shown in FIG. 1.

FIG. 4(a) is an enlarged plan view of the printed circuit board and the flexible printed circuit boards attached to the frame shown in FIG. 1, and FIG. 4(b) is a cross sectional view along the line IVb-IVb in FIG. 4(a).

FIG. 5 is a schematic cross sectional view of a liquid crystal display device of Embodiment 2 of the present invention.

FIG. 6 is a plan view of the printed circuit boards and the flexible printed circuit boards shown in FIG. 5.

FIG. 7(a) is an enlarged plan view of the printed circuit board and the flexible printed circuit boards attached to the frame shown in FIG. 5, and FIG. 7(b) is a cross sectional view along the line VIIb-VIIb in FIG. 7(a).

FIG. 8 is a schematic cross sectional view of a liquid crystal display device of Embodiment 3 of the present invention.

FIG. 9 is a plan view of the printed circuit boards and the flexible printed circuit boards shown in FIG. 8.

FIG. 10(a) is an enlarged plan view of the printed circuit board and the flexible printed circuit boards attached to the frame shown in FIG. 8, and FIG. 10(b) is a cross sectional view along the line Xb-Xb in FIG. 10(a).

### DETAILED DESCRIPTION OF EMBODIMENTS

Preferred embodiments of display devices of the present invention are described with reference to the figures. In the following description, application of the present invention to transmissive liquid crystal display devices is described using the embodiments. Dimensions of components in the figures do not reflect faithfully sizes and dimensional ratios of actual components.

### Embodiment 1

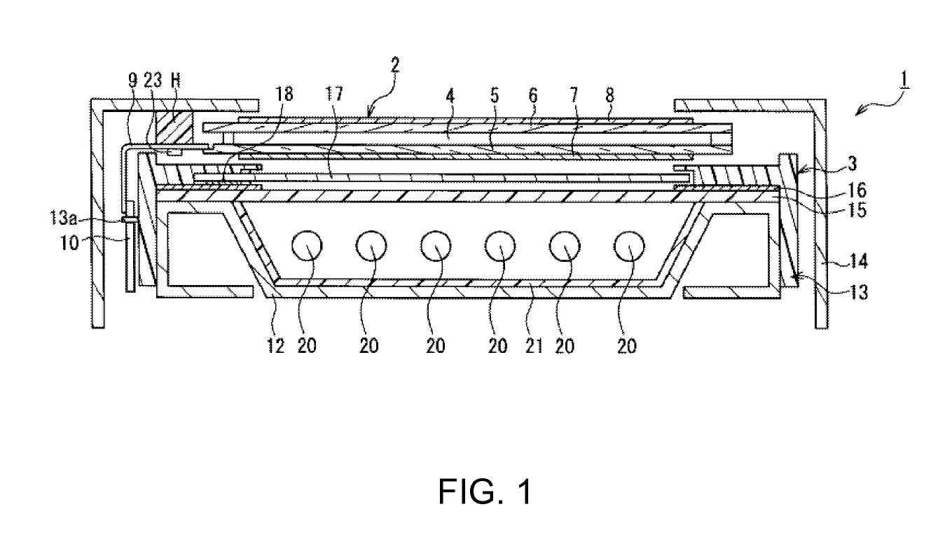

FIG. 1 is a schematic cross sectional view of a liquid crystal display device of Embodiment 1 of the present invention. In the figure, a liquid crystal display device 1 of Embodiment 1 has a liquid crystal panel 2 as a display unit with the viewer's side (display surface side) facing upward, and an illumination device 3 disposed on the non-display side (lower side in the figure) of the liquid crystal panel 2 for generating illumination light to irradiate the liquid crystal panel 2.

The liquid crystal panel 2 has a liquid crystal layer 4, an active matrix substrate 5 and a color filter substrate 6 for holding the liquid crystal layer 4 in between, and polarizing plates 7 and 8 disposed respectively on the external surfaces of the active matrix substrate 5 and the color filter substrate 6. The liquid crystal display 2 has flexible printed circuit boards 9, and printed circuit boards 10 connected electrically to the flexible printed circuit boards 9. The flexible printed circuit boards 9 and the printed circuit boards 10, as referred in detail later, are plural, and their numbers depend on the number of a plurality of source drivers 23.

Each of the flexible printed circuit boards 9 is called an SOF (System On Film), and the flexible printed circuit board 9 has a source driver 23 mounted as a driver for driving the liquid crystal layer 4 in pixels. The flexible printed circuit board 9 abuts a heat dissipation sheet H made of, for example, synthetic resin on the surface opposite to the surface on which the source driver 23 is mounted (upper surface in FIG. 1), so that heat generated in the source driver 23 is transferred via the heat dissipation sheet H to a bezel, which will be described later, and is discharged to the outside.

In the liquid crystal panel 2, the liquid crystal layer 4 modulates light polarization of the illumination light entering through the polarizing plate 7, and controls the amount of light passing through the polarizing plate 8 to display a desired image.

The liquid crystal mode and the pixel structure can be set as desired. The driving mode of the liquid crystal panel 2 can also be selected as desired. In other words, the liquid crystal panel 2 can be any liquid crystal panel, which displays information. Because of this, the structure of the liquid crystal panel 2 is not shown in detail in FIG. 1, and its description is omitted.

The illumination device 3 has a chassis 12, which is open on the upper side (the liquid crystal panel 2 side) and has the bottom, and a frame 13, which is provided closer to the liquid crystal panel 2 than the chassis 12. The chassis 12 and the frame 13 are made respectively of metal and synthetic resin, and are held by a bezel 14, which is L-shaped in cross section, with the liquid crystal panel 2 disposed over the frame 13.

To be more specific, the chassis 12 is a case for housing the illumination device 3 for accommodating cold cathode fluorescent lamps as light sources, which will be described later, and is attached integrally to the frame 13 inside the frame 13. The frame 13 has pin members 13a that functions as a mounting member for the printed circuit board 10 (which will be described in detail later).

The bezel 14 houses the liquid crystal panel (display unit) 2, and is also called as a plastic chassis. Holding the liquid crystal panel 2 with the frame 13, the bezel 14 is attached to the frame 13 and the chassis 12. The illumination device 3 is attached to the liquid crystal panel 2 to form a part of the transmissive liquid crystal display device 1 in which illumination light from the illumination device 3 enters the liquid crystal panel 2.

The illumination device 3 has a diffusion panel 15 disposed to cover the opening of the chassis 12, an optical sheet 17 disposed over the diffusion panel 15 near the liquid crystal panel 2, and a reflective sheet 21 disposed on the internal surface of the chassis 12. The illumination device 3 also has a plurality of, for example, six cold cathode fluorescent lamps 20 under the liquid crystal panel 2 in the chassis 12 to be a direct lighting device 3. In the direct illumination device 3, light from the respective cold cathode fluorescent lamps 20 goes out as illumination light from the light-emitting surface of the illumination device 3 facing the liquid crystal panel 2.

A configuration using the direct illumination device 3 has been described above; however, the present invention is not limited to it. Instead, an edge light device having a light guide panel may be used. Another illumination device having hot cathode fluorescent lamps or LEDs other than cathode fluorescent lamps may be used.

The diffusion panel 15 is made of, for example, a 2 mm-thick rectangular synthetic resin or glass material, diffuses light from the cold cathode fluorescent lamps 20 and directs it to the optical sheet 17. The four sides of the diffusion panel 15 are disposed on the upper edge surface of the chassis 12. The diffusion panel is held between the edge surface of the chassis 12 and the internal surface of the frame 13 with a pressure member 16 placed in between, and is integrated in the illumination device 3. The diffusion panel 15 is supported at the substantially central portion by a transparent support member (not shown) inside the chassis 12 to prevent bowing into chassis 12.

The diffusion panel 15 is held movably between the chassis 12 and the pressure member 16. Even if the diffusion panel 15 suffers expansion or contraction (plastic deformation) under the influence of heat such as heat generated by cold cathode fluorescent lamps 20 or temperature increase in the chassis 12, the pressure member 16 deforms elastically to absorb the plastic deformation and minimize diffusion of light from the cold cathode fluorescent lamps 20. The diffusion panel 15 is preferably made of glass which is more resistant to heat than synthetic resin, because glass is less likely to be subject to warping, yellowing, or deformation under the influence of heat.

The optical sheet 17 includes a light collection sheet made of, for example, 0.5 mm-thick synthetic resin film, and is configured to increase luminance of the illumination light to the liquid crystal panel 2. The optical sheet 17 includes, as required, a lamination of known optical sheets, such as a prism sheet, a diffusion sheet, and a polarizing sheet for improving display quality of the display surface of the liquid crystal panel 2. The optical sheet 17 is configured to convert light from the diffusion panel 15 into planar light having at least a predetermined and even luminance (for example, 10,000 cd/m²) and guide it to the liquid crystal panel 2. Besides the above description, for example, an optical member such as a diffusion sheet for adjusting the view angle of the liquid crystal panel 2 may be laminated as required over the liquid crystal panel 2 (on the display surface).

The optical sheet 17 has a projection formed on the topside: the side that would become the top when the liquid crystal display device 1 is in use—i.e., at the central portion of the left end side in FIG. 1. In the optical sheet 17, only this projection is held between the internal surface of the frame 13 and the pressure member 16 with an elastic member 18 inserted in between, and the optical sheet 17 is built extendably and shrinkably into the illumination device 3. In this configuration, even if the optical sheet 17 suffers expansion or contraction (plastic deformation) under the influence of heat such as heat generated by the cold cathode fluorescent lamps 20, the optical sheets 17 can expand or contract freely about the projection to minimize creases or bending of the optical sheet 17. As a result, the liquid crystal display device 1 minimizes deterioration in display quality of the display surface of the liquid crystal panel 2 such as uneven luminance caused by bending and the like of the optical sheet 17.

Each of the cold cathode fluorescent lamps 20 is a straight tube having electrodes (not shown) on both ends which are supported externally by the chassis 12. The cold cathode fluorescent lamp 20 is a 3.0 to 4.0 mm-wide narrow tube with high luminance efficiency, and the cold cathode fluorescent lamps 20 are held inside the chassis 12 in predetermined positions in relation to the diffusion panel 15 and the reflective sheet 21 using a light source holder, which is not shown. The cold cathode fluorescent lamps 20 are arranged with their longitudinal direction being parallel to the direction perpendicular to the direction of gravity, so that mercury (vapor) included in the cold cathode fluorescent lamps 20 does not gather in one end in the longitudinal direction owing to gravity, thus prolonging the life of the lamps substantially.

The reflective sheet 21 is made of, for example, a 0.2 to 0.5 mm-thick metallic thin film of high reflectance such as aluminum or silver, and functions as a reflective panel for reflecting light from the cold cathode fluorescent lamps 20 toward the diffusion panel 15. Using this reflective sheet, the illumination device 3 reflects efficiently light emitted by the cold cathode fluorescent lamps 20 toward the diffusion panel 15 to increase the light use efficiency and the luminance at the diffusion panel 15. Alternatively, the metallic thin film as reflective panel may be replaced with a synthetic resin reflective sheet, or the internal surface of the chassis 12 may be painted highly reflective white.

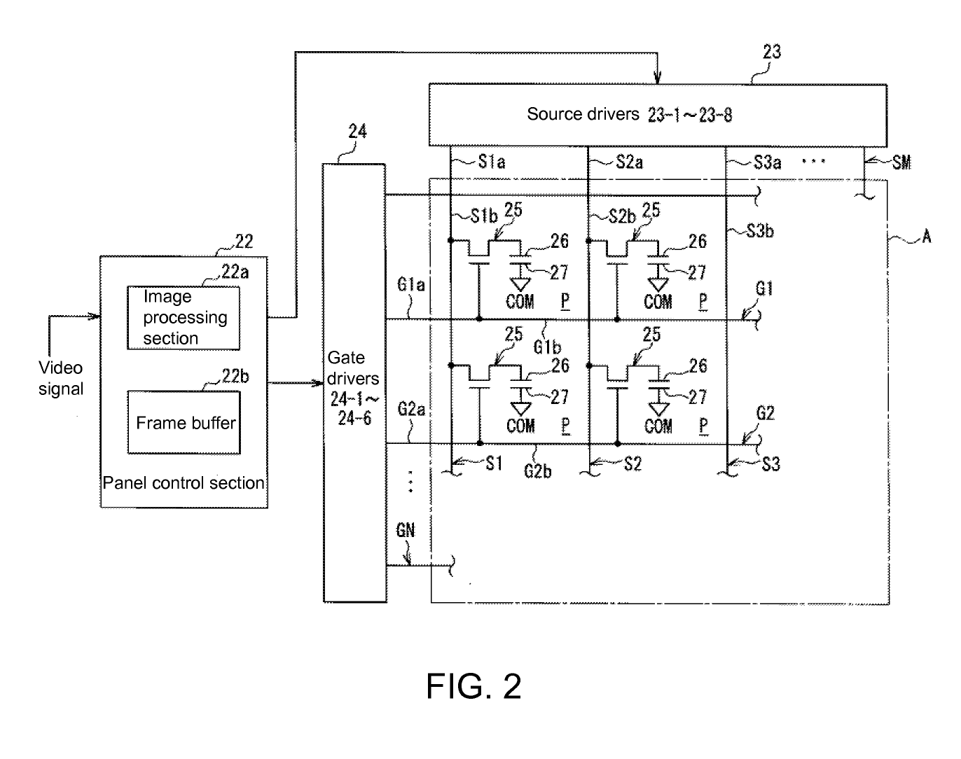

Next, the liquid crystal panel 2 will be described specifically with reference to FIG. 2.

FIG. 2 is a diagram showing a configuration of main components of the liquid crystal panel shown in FIG. 1.

In FIG. 2, the liquid crystal display device 1 (FIG. 1) has a panel control section 22 for driving and controlling the liquid crystal panel 2 (FIG. 1) as display unit for displaying information such as characters and images; a plurality of, for example, eight source drivers 23-1, 23-2, . . . , 23-7, 23-8 (hereinafter “23” collectively) operating based on instruction signals from the panel control section 22; and a plurality of, for example, six gate drivers 24-1, 24-2, . . . , 24-5, 24-6 (hereinafter “24” collectively).

The panel control section 22 receives a video signal from outside the liquid crystal display device 1. The panel control section 22 has an image processing section 22a for performing predetermined image processing on the input video signal, and generating instruction signals to the source drivers 23 and the gate drivers 24; and a frame buffer 22b capable of storing a frame of display data included in the input video signal. The panel control section 22, according to the input video signal, drives and controls the source drivers 23 and the gate drivers 24 to display information according to the video signal on the liquid crystal panel 2.

The source drivers 23, as described above, are mounted on the flexible printed circuit boards 9. Similarly, the gate drivers 24 are mounted on the flexible printed circuit boards, which will be described later. The source drivers 23 and the gate drivers 24 are drive circuits for driving a plurality of pixels P pixel-by-pixel in an effective display region A of the liquid crystal panel 2, and the source drivers 23 and the gate drivers 24 have a plurality of source wires S1-SM (M is 8 or larger integer, and hereinafter referred to as “S” collectively), and a plurality of gate wires G1-GN (N is 6 or larger integer, and hereinafter referred to as “N” collectively).

The source wires S and the gate wires G are arranged in a matrix at least within the effective display region A, and in respective matrix blocks, regions of the plurality of pixels P are formed. More specifically, as shown in FIG. 2, the source wires S include source wire main segments S1b, S2b, S3b, . . . , arranged in parallel and vertically in the liquid crystal panel 2; and connection wires S1a, S2a, S3a, . . . , for connecting the source wire main segments S1b, S2b, S3b, . . . , and the source drivers 23 in the shortest distances. Similarly, the gate wires G include gate wire main bodies G1b, G2b, . . . , arranged in parallel and laterally in the liquid crystal panel 2; and connection wires G1a, G2a, . . . , for connecting the gate wire main bodies G1b, G2b, . . . and the gate drivers 24 in the shortest distances.

The plurality of pixels P include red, green, and blue pixels. The red, green, and blue pixels are arranged, for example, in this order in parallel with the gate wire main segments G1b, G2b, . . . , of the gate wires G.

While a gate for a switching element 25 for each pixel P is connected to the respective gate wire main segments G1b, G2b, . . . , a source for the switching element 25 is connected to the respective source wire main segments S1b, S2b, S3b, . . . A pixel electrode 26 for each pixel P is connected to a drain of the respective switching element 25. For each pixel P, a common electrode 27 is arranged opposite to the pixel electrode 26 with the liquid crystal layer 4 (FIG. 1) of the liquid crystal panel 2 held in between. The gate drivers 24 output sequentially to the gate wires G1-GN scan signals which turn on the gates of the corresponding switching elements 25, and the source drivers 23 output to the corresponding source wires S1-SM voltage signals (gradation voltage) according to the luminance (gradation) of a displayed image based on the instruction signals from the image processing section 22a.

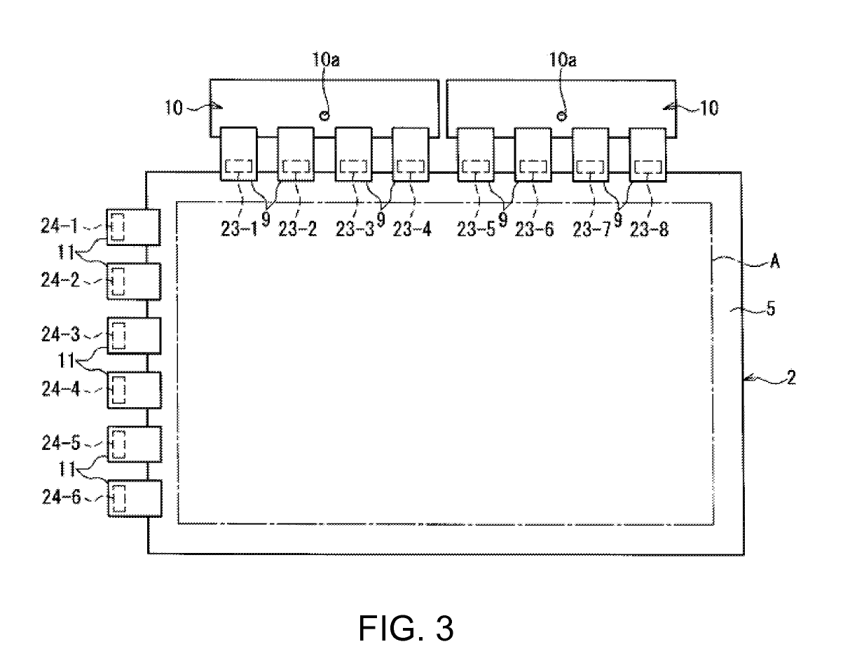

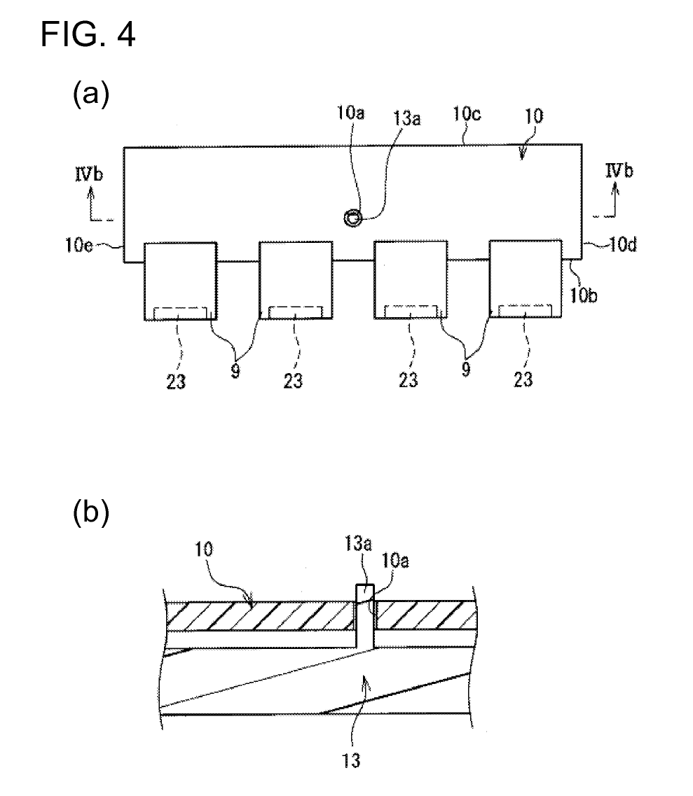

Next, the flexible printed circuit boards 9 and the printed circuit boards 10 will be described with reference to FIGS. 3 and 4.

FIG. 3 is a plan view of the printed circuit boards and the flexible printed circuit boards shown in FIG. 1. FIG. 4(a) is an enlarged plan view of the printed circuit board and the flexible printed circuit boards attached to the frame shown in FIG. 1, and FIG. 4(b) is a cross sectional view along the line IVb-IVb in FIG. 4(a).

First, the connection between the active matrix substrate 5, the source drivers 23 and the gate drivers 24 will be described specifically with reference to FIG. 3.

As shown in FIG. 3, in the liquid crystal panel 2, the eight source drivers 23-1 to 23-8 are mounted respectively to the eight flexible printed circuit boards (SOFs) 9. One end of each flexible printed circuit board 9 is connected to the source wires S outside the effective display region A on the active matrix substrate 5. The source drivers 23-1 to 23-8 have the same number (M/8) of source wires S connected.

The other end of each flexible printed circuit board 9 is connected to the printed circuit board 10. More specifically, as shown in FIG. 3, two printed circuit boards 10 are provided in the liquid crystal panel 2, and four flexible printed circuit boards 9 are connected to each printed circuit board 10. In the liquid crystal panel 2, the instruction signals according to information to be displayed in the display unit of the liquid crystal panel 2 are input from the image processing section 22a in the panel control section 22 to the respective source drivers 23-1 to 23-8. Then, the source drivers 23-1 to 23-8 output the voltage signals to the corresponding source wires S.

In the liquid crystal panel 2, the six source drivers 24-1 to 24-6 are mounted respectively to six flexible printed circuit boards (SOFs) 11. One end of each flexible printed circuit board 11 is connected to the gate wires G outside the effective display region A on the active matrix substrate 5. The gate drivers 24-1 to 24-6 have the same number (N/6) of gate wires G connected. The gate drivers 24-1 to 24-6 are connected to the panel control section 22 via wires (not shown) provided on the corresponding flexible printed circuit boards 11 and the active matrix substrate 5. The gate drivers 24-1 to 24-6 receive the instruction signals from the image processing section 22a, and output the scan signals to the corresponding gate wires G.

In the liquid crystal panel 2, the flexible printed circuit boards 9 and 11 are bent against the active matrix substrate 5, allowing the flexible printed circuit boards 9 and 11, and the printed circuit boards 10 housed in the bezel 14 as shown in FIG. 1. The printed circuit boards 10 are attached to the frame 13 with the pin members 13a on the frame 13 as shown in FIG. 1.

Attachment of the printed circuit board 10 to the frame 13 will be described specifically with reference to FIG. 4.

As shown in FIG. 4(a), the printed circuit board 10 to be used is rectangular, and the printed circuit board 10 has longer sides 10b and 10c, and shorter sides 10d and 10e. The printed circuit board 10 has a predetermined pattern of wiring (not shown) on the surface, and four connectors (not shown) are disposed thereon. In the printed circuit boards 10, the four connectors are respectively connected electrically to the four flexible printed circuit boards 9.

In the printed circuit board 10, an insertion hole 10a in which the pin member 13a is inserted is provided at the substantially central portion of one side, or the longer side 10b (at the substantially central portion in the lateral direction in the figure). In other words, the insertion hole 10a is provided in the vicinity of the substantially central ones of the four flexible printed circuit boards 9 arranged in a line on the longer side 10b (that is, between the second and third flexible printed circuit boards 9 from the left in the figure). When the flexible printed circuit boards 9 are bent against the active matrix substrate 5, the pin member 13a of the frame 13 is inserted into the insertion hole 10a of the printed circuit board 10. When the pin member 13a of the frame 13 is inserted into the insertion hole 10a of the printed circuit board 10, the printed circuit board 10 is attached to the frame 13 at the substantially central portion of the longer side 10b to which the flexible printed circuit boards 9 are connected, and in the vicinity of the substantially central flexible printed circuit boards 9. (See also FIG. 4(b).)

By attaching the printed circuit board 10 in the vicinity of the substantially central flexible printed circuit boards 9 to the frame 13 as shown above, even if the printed circuit board 10 suffers deformation such as elongation due to change in a surrounding environment such as temperature and humidity, the printed circuit board 10 is attached to the frame 13 movably in the lateral and vertical directions in FIG. 4(a) so that it can absorb such deformation.

In the liquid crystal display device 1 of the embodiment thus configured, each of the printed circuit boards 10 is attached to the frame (mounting member) 13 at the substantially central portion of the longer side (one side) 10b to which the flexible printed circuit boards 9 are connected in the vicinity of the flexible printed circuit boards 9. In this configuration, unlike the conventional art, even if the printed circuit boards 10 suffer deformation such as elongation, the flexible printed circuit boards 9 are saved from deformation such as elongation as the printed circuit boards 10 deform. As a result, the liquid crystal display device 1 of this embodiment, unlike the conventional art, prevents the flexible printed circuit boards 9 from being damaged even if the printed circuit boards 10 suffer deformation such as elongation.

In this embodiment, because the printed circuit board 10, as shown in FIG. 4(a), is attached to the frame 13 in the vicinity of the substantially central ones of the four flexible printed circuit boards 9 arranged in a line, even if the printed circuit board 10 suffers deformation such as elongation, each of the plurality of the flexible printed circuit boards 9 are saved from being damaged.

Alternatively, two or more pin members 13a may be used to attach each printed circuit boards 10 to the frame 13.

### Embodiment 2

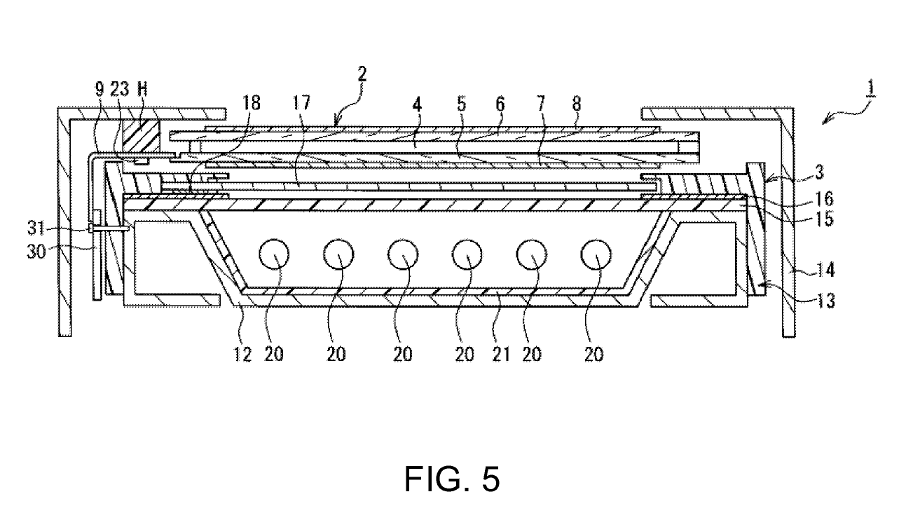

FIG. 5 is a schematic cross sectional view of a liquid crystal display device of Embodiment 2 of the present invention. In the figure, Embodiment 2 of the present invention is generally identical to Embodiment 1 except that the printed circuit boards are attached to the frame and the chassis with screw members. The elements common to Embodiment 1 will be indicated by the same reference characters, and description will be omitted to avoid duplication.

As shown in FIG. 5, in the liquid crystal display device 1, a printed circuit board 30 is attached to the frame 13 and the chassis 12 as mounting members with a screw member 31. The screw member 31 is made of metal. The printed circuit board 30 is grounded via the screw member 31 and the chassis 12.

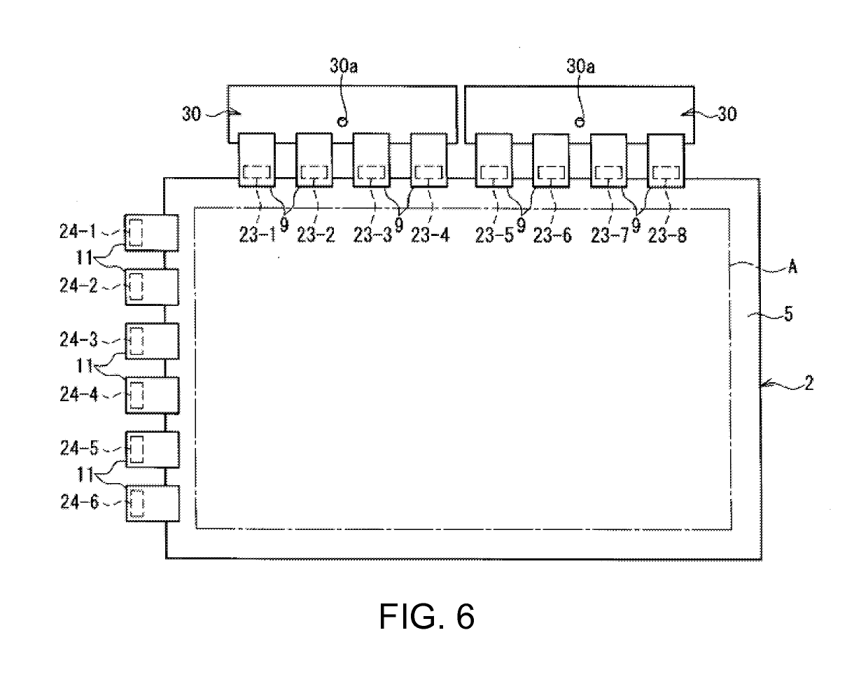

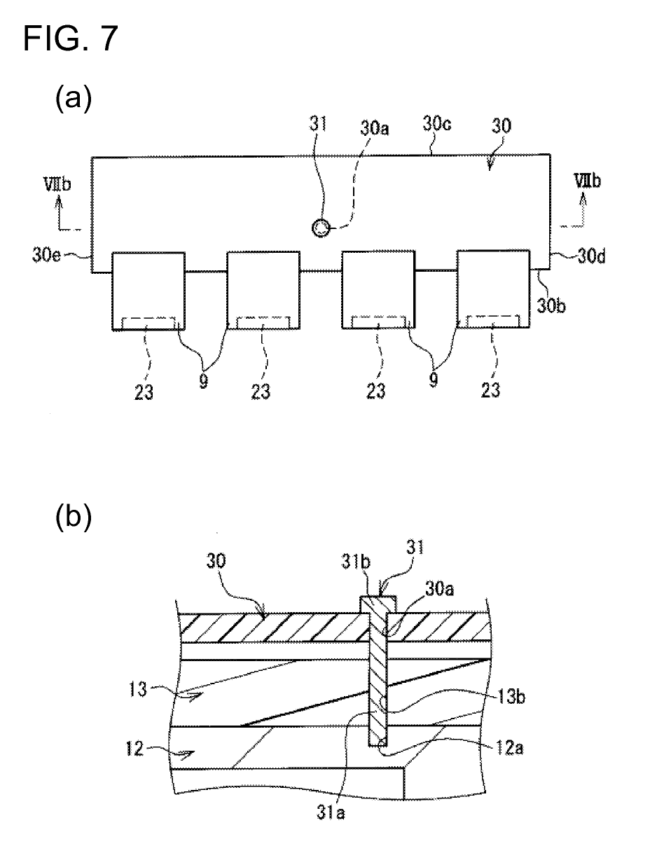

The flexible printed circuit boards 9 and the printed circuit boards 30 will be described specifically with reference to FIGS. 6 and 7.

FIG. 6 is a plan view of the printed circuit boards and the flexible printed circuit boards shown in FIG. 5. FIG. 7(a) is an enlarged plan view of the printed circuit board and the flexible printed circuit boards attached to the frame shown in FIG. 5, and FIG. 7(b) is a cross sectional view along the line VIIb-VIIb in FIG. 7(a).

As shown in FIG. 6, the liquid crystal panel 2 has two printed circuit boards 30, each one of which has four printed circuit boards 9 connected to it. Each of the flexible printed circuit boards 9, similarly to Embodiment 1, has the source drivers 23 mounted on it. Each of the printed circuit boards 30 has a screw hole 30a in which the screw member 31 is inserted.

Specifically, as shown in FIG. 7(a), the printed circuit board 30 is rectangular, and has longer sides 30b and 30c, and shorter sides 30d and 30e. The printed circuit board 30 has a predetermined pattern of wiring which is not shown on the surface, and similarly to Embodiment 1, the four flexible printed circuit boards 9 are respectively connected electrically to four connectors (not shown).

The printed circuit board 30 has the screw hole 30a at the substantially central portion of one side, or the longer side 30b (at the substantially central portion in the lateral direction in the figure). In other words, the screw hole 30a is formed in the vicinity of the substantially central ones of the four flexible printed circuit boards 9 in a line on the longer side 30b in the lateral direction in the figure (that is, between the second and third flexible printed circuit boards 9 from the left in the figure). In the printed circuit board 30, when the flexible printed circuit boards 9 are bent against the active matrix substrate 5, the screw member 31 is inserted into the screw hole 30a. Threads 31a of the screw member 31 are engaged with the screw hole 30a, as shown in FIG. 7(b), and then with screw holes 13b and 12a prepared respectively in the frame 13 and the chassis 12. Now, the printed circuit board 30 is attached to the frame 13 and the chassis 12 at the substantially central portion of the longer side 30b to which the flexible printed circuit boards 9 are connected in the vicinity of the substantially central flexible printed circuit boards 9.

Thus, the printed circuit board 30 is attached to the frame 13 in the vicinity of the substantially central flexible printed circuit boards 9 as shown above. In this configuration, the printed circuit board 30 is attached movably in the lateral and vertical directions in FIG. 7(a) to the frame 13 and the chassis 12 to absorb deformation such as elongation, if any, due to change in the surrounding environment such as temperature and humidity.

In this embodiment, as shown in FIG. 7(b), the head 31b of the screw member 31 is connected electrically to a ground wire (not shown) on the surface of the printed circuit board 30. When the threads 31a of the screw member 31 are engaged with the screw hole 12a of the chassis 12, the ground wire is connected electrically to the chassis 12 via the screw member 31, and the printed circuit board 30 is grounded through the screw member 31 and the chassis 12.

This embodiment of the above configuration has function and effects similar to those of Embodiment 1. In this embodiment, because the printed circuit board 30 is attached to the frame 13 and the chassis 12 with the screw member 31, the printed circuit board 30 is attached more stably.

Alternatively, two or more screw members 31 may be used to attach the printed circuit board 30 to the frame 13 and the chassis 12.

### Embodiment 3

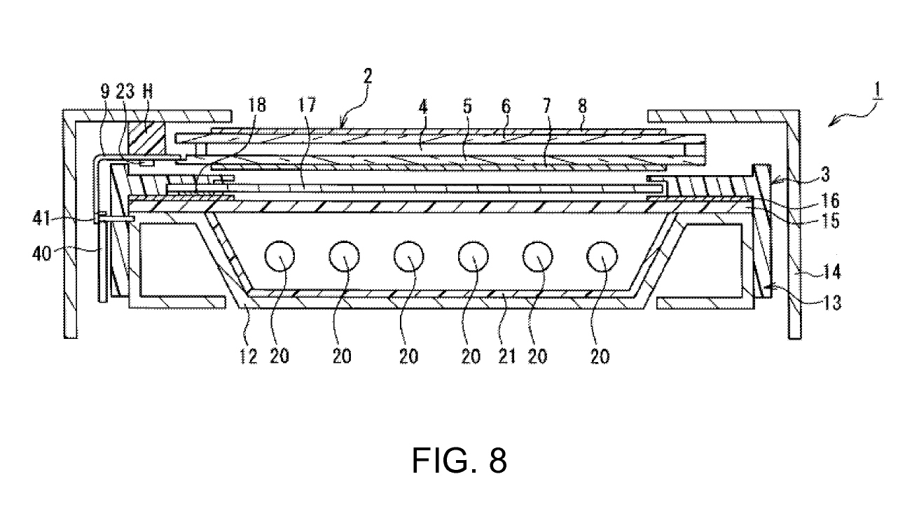

FIG. 8 is a schematic cross sectional view of a liquid crystal display device of Embodiment 3 of the present invention. In the figure, this embodiment is generally identical to Embodiment 2 except that screw members are provided closer to the one side of the printed circuit boards than the end side of the flexible printed circuit board. The elements common to Embodiment 2 will be indicated by the same reference characters, and the description will be omitted to avoid duplication.

As shown in FIG. 8, in the liquid crystal display device 1 of the present embodiment, a printed circuit board 40 is attached to the frame 13 and the chassis 12 as mounting members with screw members 41. The screw members 41 are made of metal. The printed circuit board 40 is grounded via the screw members 41 and the chassis 12.

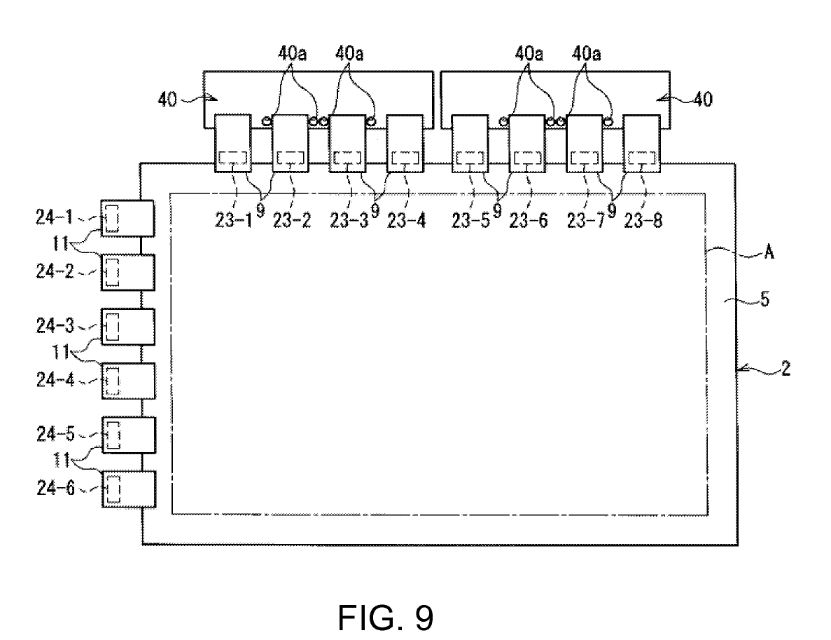

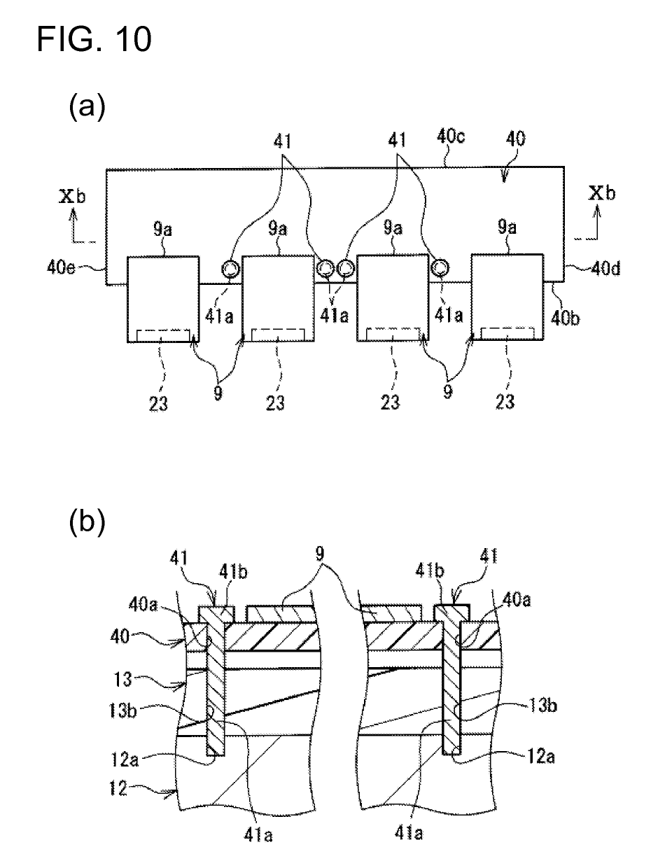

The flexible printed circuits 9 and the printed circuit boards 30 will be described specifically with reference to FIGS. 9 and 10.

FIG. 9 is a plan view of the printed circuit boards and the flexible printed circuit boards shown in FIG. 8. FIG. 10(a) is an enlarged plan view of the printed circuit board and the flexible printed circuit boards attached to the frame shown in FIG. 8, and FIG. 10(b) is a cross sectional view along the line Xb-Xb in FIG. 10(a).

As shown in FIG. 9, the liquid crystal panel 2 has two printed circuit boards 40, and each of the printed circuit boards 40 is connected to the four flexible printed circuit boards 9. Each of the flexible printed circuit boards 9, similarly to Embodiment 2, has the source drivers 23 mounted on it. Each of the printed circuit boards 40 has four screw holes 40a into which the four screw members 41 are turned.

Specifically, as shown in FIG. 10(a), the printed circuit board 40 is rectangular, and has longer sides 40b and 40c, and shorter sides 40d and 40e. The printed circuit board 40 has a predetermined pattern of wiring which is not shown on the surface, and similarly to Embodiment 2, the four flexible printed circuit boards 9 are respectively connected electrically to four connectors (not shown).

The printed circuit board 40 has four screw holes 40a at the substantially central portion of one side, or the longer side 40b (at the substantially central portion in the lateral direction in the figure). Specifically, the four screw holes 40a, as shown in FIG. 10(a), are formed on both sides of the second and third ones from the left in the figure of the four flexible printed circuit boards 9 arranged in a line on the longer side 40b.

In the embodiment, the four screw holes 40a are provided in the vicinity of the longer side 40b so that the screw members 41 are attached closer to the longer side 40b of the printed circuit board 40 than the end side 9a of the flexible printed circuit board 9.

When the flexible printed circuit boards 9 are bent against the active matrix substrate 5, the screw members 41 in the printed circuit board 40 are turned into the screw holes 40a. After engaged with the screw holes 40a as shown in FIG. 10(b), threads 41a of the screw members 41 are farther engaged with the screw holes 13b and 12a which are provided respectively in the frame 13 and the chassis 12. Thus, the printed circuit board 40 is attached to the frame 13 and the chassis 12 at the substantially central portion of the longer side 40b to which the flexible printed circuit boards 9 are connected in the vicinity of the substantially central flexible printed circuit boards 9.

Thus, the printed circuit board 40 is attached to the frame 13 in the vicinity of the substantially central flexible printed circuit boards 9 as shown above. In this configuration, the printed circuit board 40 is attached movably in the lateral and vertical directions in FIG. 10(a) to the frame 13 and the chassis 12 to absorb deformation such as elongation, if any, due to change in the surrounding environment such as temperature and humidity.

In this embodiment, as shown in FIG. 10(b), the heads 41b of the screw members 41 are connected electrically to ground wires (not shown) on the surface of the printed circuit board 40. When the threads 41a of the screw members 41 are engaged with the screw holes 12a of the chassis 12, the ground wires are connected electrically to the chassis 12 via the screw members 41, and the printed circuit board 40 is grounded through the screw members 41 and the chassis 12.

This embodiment of the above configuration has the function and effects similar to those of Embodiment 2. In the embodiment, because the screw members 41 are attached closer to the longer side 40b of the printed circuit board 40 than the end side 9a of the flexible printed circuit board 9, even if the printed circuit board 40 suffers deformation such as elongation, the flexible printed circuit boards 9 are more securely saved from deformation such as elongation and damages.

While an example with the four screw members 41 has been described above, this embodiment is not limited to this, and may take another configuration as long as the screw members 41 are provided closer to the longer side 40b of the printed circuit board 40 than the end side 9a of the flexible printed circuit boards 9 in the vicinity of the substantially central flexible printed circuit boards 9.

All of the above embodiments are only exemplary, and are not exclusive. The technical field of the present invention is defined by claims, and includes configurations in the claims and equivalents thereof including all modifications.

For example, the present invention has been described above using a transmissive liquid crystal display device. However, the present invention is not limited to this, and may be any display device having a display part which has a plurality of pixels, configured to display information. More specifically, the present invention may be applied to various display devices such as semi-transmissive and reflective liquid crystal display devices, organic EL (electronic luminescence) displays, and PDPs (plasma display panels).

In the above descriptions, the flexible printed circuit boards (SOFs) have eight source drivers in total, and four source drivers are connected to each one of the rectangular printed circuit boards. However, the present invention is not limited to this configuration, and may be any display device as long as it has printed circuit boards and flexible printed circuit boards which are connected electrically to the printed circuit boards, and the printed circuit boards are attached to a mounting member at the substantially central portion of one side to which the flexible printed circuit boards are connected in the vicinity of the flexible printed circuit boards.

Specifically, the present invention may take, for example, a configuration in which flexible printed circuit boards are connected to at least one source driver, which is COG (chip on glass) mounted on the active matrix substrate of the liquid crystal panel, and are also connected to the printed circuit boards. The present invention may take another configuration in which the gate drivers are mounted on a plurality of flexible printed circuit boards (SOFs) which are connected to the printed circuit boards as shown above.

However, as shown in the above embodiments, the configurations in which the source drivers and the gate drivers are mounted on the flexible printed circuit boards are preferable because the structure of the display device is simple.

While the frame and the chassis are used as the mounting members in the above descriptions, the mounting members in the present invention are not limited to them, and may be any member on which the printed circuit boards are mounted.

However, use of the frame and/or the chassis as shown in the above embodiments is preferable because it reduces the number of components and makes a display device simpler. The use of the frame and/or the chassis is particularly preferable when the printed circuit boards are attached to the chassis which houses the illumination device as shown in Embodiments 2 and 3, because the liquid display device is compact while preventing the flexible printed circuit boards from being damaged.

The configurations in which the screw members are turned into the frame and the chassis have been described in Embodiments 2 and 3. However, the present invention is not limited to these, and may take any configuration in which the printed circuit boards are attached to at least the chassis as the mounting member. This configuration is particularly preferable when the chassis and the screw members are made of metal, and the printed circuit boards are grounded via the screw members and the chassis as shown in Embodiments 2 and 3, because the printed circuit boards are grounded in a simple manner.

### INDUSTRIAL APPLICABILITY

The present invention is applicable to a display device which prevents damages to flexible printed circuit boards even if printed circuit boards suffer deformation such as elongation.

### DESCRIPTION OF REFERENCE CHARACTERS

1 liquid crystal display device (display device)
2 liquid crystal panel (display unit)
3 illumination device
9 flexible printed circuit board
9a end side
10, 30, 40 printed circuit board
10a insertion hole
10b, 30b, 40b longer side (one side)
12 chassis (mounting member, case)
13 frame (mounting member)
13a pin member
31, 41 screw member
20 cold cathode fluorescent lamp (light source)
23 source driver (driver)
P pixel

1. A display device having a display unit having a plurality of pixels to display information on the display unit, comprising:
a printed circuit board; and
a plurality of flexible printed circuit boards electrically connected to said printed circuit board,
wherein said printed circuit board is attached to a mounting member at a substantially central portion of one side thereof to which said flexible printed circuit boards are connected, in the vicinity of said flexible printed circuit boards.

2. The display device according to claim 1, wherein said plurality of flexible printed circuit boards are arranged in a line on one side of said printed circuit board and are connected electrically to said printed circuit board, and said printed circuit board is attached to said mounting member in the vicinity of substantially central ones of said flexible printed circuit boards on said side among said plurality of flexible printed circuit boards.

3. The display device according to claim 1, further comprising a bezel for housing the display unit and a frame attached to said bezel,
wherein said frame has a pin member projecting on a side of said printed circuit board,
wherein said printed circuit board has an insertion hole in which said pin member is inserted, and
wherein said printed circuit board is attached to said frame as a mounting member when said pin member is inserted into said insertion hole.

4. The display device according to claim 1, further comprising a bezel for housing the display unit, a frame attached to said bezel, and a chassis provided inside said frame and attached to said frame,
wherein said printed circuit board is attached with a screw member to at least said chassis as a mounting member among said frame and said chassis.

5. The display device according to claim 4, wherein said screw member in said printed circuit board is attached closer to said one side thereof than the end side of said flexible printed circuit boards.

6. The display device according to claim 4, wherein said chassis and said screw member are made of metal, and said printed circuit board is grounded via said screw member and said chassis.

7. The display device according to claim 4, wherein said display unit includes a liquid crystal panel, and said chassis is a case for housing a light source in an illumination device for emitting illumination light toward said liquid crystal panel.

8. The display device according to claim 1, wherein drivers for driving said plurality of pixels are mounted in said flexible printed circuit boards.
